(19) United States
(12) Patent Application Publication
(10) Pub. No.: US 2026/0026283 A1
(43) Pub. Date: Jan. 22, 2026

(54) GAS SUPPLY MECHANISM, SEMICONDUCTOR MANUFACTURING SYSTEM, AND REMAINING AMOUNT MONITORING METHOD

(71) Applicant: Tokyo Electron Limited, Tokyo (JP)

(72) Inventors: Hideki NAGAOKA, Yamanashi (JP); Kensaku NARUSHIMA, Yamanashi (JP); Kohichi SATOH, Gyeonggi-do (KR); Tomoyuki KASHIWAGI, Yamanashi (JP)

(21) Appl. No.: 19/261,104

(22) Filed: Jul. 7, 2025

(30) Foreign Application Priority Data
Jul. 16, 2024 (JP) 2024-113551

(51) Int. Cl. H01L 21/67; H01J 37/32

(52) U.S. Cl. CPC H01L 21/67017; H01J 37/3244

(57) ABSTRACT

With respect to a gas supply mechanism for supplying a raw material gas obtained by vaporizing a raw material, the gas supply mechanism includes an inner container configured to contain the raw material; an outer container having a space in which the inner container is accommodated such that the inner container is relatively displaceable and allowing the raw material gas generated from the raw material in the inner container to flow out to an outside; and a detector configured to detect an index related to a weight of the inner container. The space of the outer container is depressurized to a vacuum atmosphere lower than an atmospheric pressure before the detector detects the index related to the weight of the inner container.

### CROSS-REFERENCE TO RELATED APPLICATIONS

This patent application is based on and claims priority to Japanese Patent Application No. 2024-113551 filed on Jul. 16, 2024, the entire contents of which are incorporated herein by reference.

### TECHNICAL FIELD

The present disclosure relates to a gas supply mechanism, a semiconductor manufacturing system, and a remaining amount monitoring method.

### BACKGROUND

Patent Document 1 discloses a semiconductor manufacturing system (a semiconductor manufacturing device) for supplying a gas obtained by vaporizing a raw material (a liquid material) to a processing section. The semiconductor manufacturing system detects the liquid level of the raw material by sound waves, to recognize the timing of replacement of a tank containing the raw material or the timing of filling the tank with the raw material.

### RELATED ART DOCUMENT

### Patent Document

[Patent Document 1] Japanese Patent No.

### SUMMARY

According to one aspect of the present disclosure, with respect to a gas supply mechanism for supplying a raw material gas obtained by vaporizing a raw material, the gas supply mechanism includes an inner container configured to contain the raw material; an outer container having a space in which the inner container is accommodated such that the inner container is relatively displaceable and allowing the raw material gas generated from the raw material in the inner container to flow out to an outside; and a detector configured to detect an index related to a weight of the inner container. The space of the outer container is depressurized to a vacuum atmosphere lower than an atmospheric pressure before the detector detects the index related to the weight of the inner container.

### BRIEF DESCRIPTION OF THE DRAWINGS

FIG. 1 is a diagram schematically illustrating a semiconductor manufacturing system according to an embodiment;

FIG. 2 is an enlarged cross-sectional view illustrating a raw material supply source according to the embodiment;

FIG. 3A is a flowchart illustrating an example of a substrate processing method of semiconductor manufacturing system;

FIG. 3B is a flowchart illustrating an example of a remaining amount monitoring method; and

FIG. 4 is a cross-sectional view illustrating a raw material supply source according to a modified example.

### DETAILED DESCRIPTION

According to one aspect, a remaining amount of a raw material can be accurately recognized.

Embodiments of the present disclosure will be described below with reference to the drawings. In the drawings, the same components are denoted by the same reference numerals, and duplicate descriptions may be omitted.

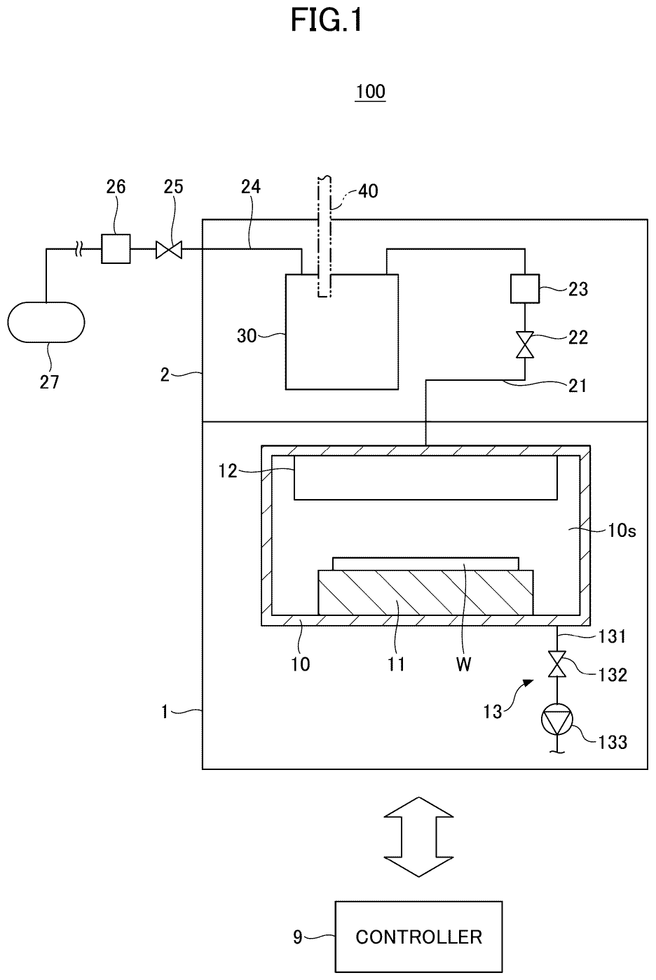

FIG. 1 is a diagram schematically illustrating a semiconductor manufacturing system 100 according to an embodiment. As illustrated in FIG. 1, the semiconductor manufacturing system 100 includes a semiconductor manufacturing apparatus 1 configured to process a substrate W, which is a semiconductor device, a gas supply mechanism 2 configured to supply, to the semiconductor manufacturing apparatus 1, a gas used in the processing, and a controller 9 configured to control the components.

The semiconductor manufacturing apparatus 1 is a substrate processing apparatus that performs substrate processing, such as film deposition processing, etching processing, cleaning processing, modification processing, and ashing processing, on the substrate W. Hereinafter, the semiconductor manufacturing apparatus 1 that performs film deposition processing will be representatively described. In this case, the semiconductor manufacturing apparatus 1 includes a processing chamber 10, a substrate support 11, a shower head 12, a gas exhaust section 13, and the like.

The processing chamber 10 is formed of aluminum alloy or the like and is formed in a cylindrical shape having a processing space 10s inside. The semiconductor manufacturing apparatus 1 opens a gate valve, which is not illustrated, provided on a side wall of the processing chamber 10, and carries the substrate W into and out of the processing space 10s.

The substrate support 11 is installed on the bottom of the processing chamber 10, and the substrate W is mounted on the top surface of the substrate support 11. The substrate support 11 includes a chuck device configured to fix the substrate W, a temperature adjustment module configured to adjust the temperature of the substrate W (both not illustrated), and the like.

The shower head 12 discharges a processing gas, a purge gas, and the like to the processing space 10s. A gas diffusion chamber for diffusing the gas is provided inside the shower head 12. A plurality of gas holes for enabling communication between the gas diffusion chamber and the processing space 10s are provided on the lower surface of the shower head 12 (a surface facing the substrate support 11). Additionally, the semiconductor manufacturing apparatus 1 connects a gas supply path 21 of the gas supply mechanism 2 to the shower head 12, and supplies a processing gas (a raw material gas, a carrier gas, and the like) to the gas diffusion chamber via the gas supply path 21, and discharges the processing gas from each of the gas holes.

The substrate support 11, the shower head 12, or both may be configured to perform plasma processing to generate plasma in the processing space 10s by power for plasma generation being supplied from a power source, which is not illustrated. For example, the substrate support 11 may function as a lower electrode during plasma processing, and the shower head 12 may function as an upper electrode during plasma processing.

The gas exhaust section 13 includes an exhaust path 131 for exhausting the gas in the processing chamber 10. The exhaust path 131 communicates with the processing space 10s through an exhaust port of the processing chamber 10. Additionally, the gas exhaust section 13 includes a pressure regulating valve 132, a vacuum pump 133, and the like at appropriate positions in the exhaust path 131. The pressure regulating valve 132 and the vacuum pump 133 are connected to the controller 9, and are controlled by the controller 9.

The semiconductor manufacturing apparatus 1 described above is mounted on an apparatus frame, which is not illustrated, and installed at an appropriate position such as a clean room. The gas supply mechanism 2 is mounted on the same apparatus frame as the semiconductor manufacturing apparatus 1, for example, and is disposed above the processing chamber 10. The gas supply mechanism 2 supplies the processing gas to the shower head 12 from above the processing chamber 10 via the gas supply path 21.

The gas supply mechanism 2 includes one or more raw material supply sources 30 (there is one in FIG. 1). The gas supply path 21 of the gas supply mechanism 2 connects the raw material supply source 30 to the shower head 12 of the processing chamber 10. Furthermore, the gas supply mechanism 2 includes a valve 22 configured to open and close a flow path of the gas supply path 21, a flow rate regulator 23 configured to adjust the flow rate of the gas flowing through the gas supply path 21, and the like. The valve 22 and the flow rate regulator 23 are connected to the controller 9, and are controlled by the controller 9.

The raw material supply source 30 is a gas source configured to supply, to the gas supply path 21, the main raw material gas contained in the processing gas. The raw material supply source 30 according to the embodiment contains a solid raw material inside as the raw material, and the raw material gas vaporized (sublimated) from the solid raw material can be discharged. A specific configuration of the raw material supply source 30 will be described in detail later.

The solid raw material in the raw material supply source 30 is not particularly limited, but examples of the solid raw material include chlorinated compounds, such as aluminum chloride (AlC₁₃) and copper chloride (CuCl₂). Alternatively, the raw material may be metal organics, such as Si, Hf, Ta, Zr, Al, Ti, Zn, In, Ga, and P, or other solid raw materials. Here, the raw material contained in the raw material supply source 30 is not limited to the solid raw material, but may be a liquid raw material. That is, “vaporization” in this specification includes a concept of sublimation of the solid raw material into a gas and a concept of evaporation of the liquid raw material into a gas.

Additionally, the gas supply mechanism 2 includes a carrier gas supply configured to supply a carrier gas to the upstream side (the primary side) of the raw material supply source 30. The carrier gas is mixed with the raw material gas in the raw material supply source 30 and serves to convey the raw material gas to the processing chamber 10 via the gas supply path 21. The carrier gas supply includes a carrier gas supply path 24, a valve 25 and a regulator 26 provided at intermediate positions of the carrier gas supply path 24, and a storage tank 27 for the carrier gas provided at the upstream end of the carrier gas supply path 24.

As for the carrier gas supplied by the carrier gas supply, an appropriate gas is selected according to the raw material gas of the raw material supply source 30 and the like. Examples of the carrier gas include an inert gas, such as argon (Ar), helium (He), and nitrogen (N₂). The storage tank 27 stores a compressed carrier gas. The valve 25 is connected to the controller 9 and opens and closes the flow path of the carrier gas supply path 24 under the control of the controller 9. The regulator 26 reduces the pressure of the carrier gas supplied from the storage tank 27 to a set pressure.

The above-described gas supply mechanism 2 supplies the raw material gas vaporized from the raw material to the semiconductor manufacturing apparatus 1 as the processing gas mixed with carrier gas under the control of the controller 9, to perform substrate processing based on the raw material gas. To the controller 9, a computer including a processor, a memory, an input/output interface, and the like is applied. The controller 9 accurately recognizes the remaining amount of the raw material in the raw material supply source 30, thereby prompting filling of the raw material or replacement of the raw material supply source 30 at an appropriate timing. Alternatively, the controller 9 may adjust the supply amount (concentration) of the raw material gas, adjust the processing period, or the like based on the remaining amount of the raw material. Thus, the raw material supply source 30 has a structure to enhance the detection accuracy of the remaining amount of the raw material.

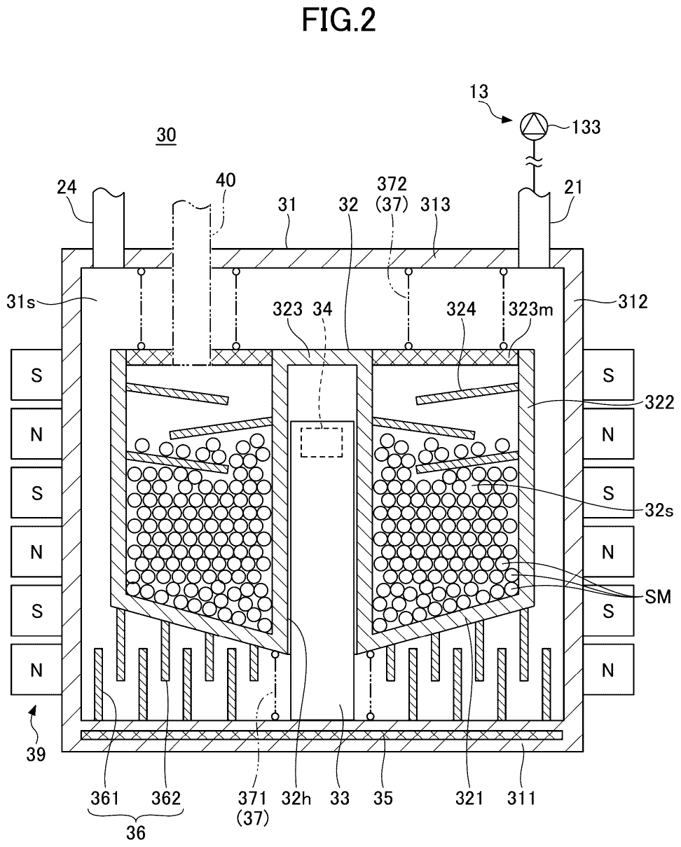

Next, the configuration of the raw material supply source 30 according to the embodiment will be specifically described with reference to FIG. 2. FIG. 2 is an enlarged cross-sectional view of the raw material supply source 30.

The raw material supply source 30 includes an outer container 31 and an inner container 32 housed in the outer container 31 such that the inner container 32 is displaceable. That is, the inner container 32 is a member displaced relatively to the outer container 31 within the outer container 31.

The outer container 31 is formed in a cylindrical (or rectangular) box having a bottom wall 311, a side wall 312, and a top wall 313. A space 31s capable of housing the inner container 32 is provided inside the outer container 31. The gas supply path 21 and the carrier gas supply path 24 described above are connected to the outer container 31. The space 31s of the outer container 31 communicates with the processing chamber 10 and the gas exhaust section 13 of the semiconductor manufacturing apparatus 1 via the gas supply path 21. Therefore, the outer container 31 can be depressurized to a vacuum atmosphere by the gas exhaust section 13 via the processing chamber 10. Here, in FIG. 2, connection positions of the gas supply path 21 and the carrier gas supply path 24 to the outer container 31 are in the top wall 313, but the connection positions may be designed according to the specific gravity of the source gas or carrier gas, or the like, and may be in the bottom wall 311 or the side wall 312.

Additionally, the outer container 31 includes a column 33 at the center of the bottom wall 311. The column 33 is formed in a cylindrical shape, for example, and extends vertically upward from the bottom wall 311 along the central axis of the space 31s. The column 33 has a guiding function capable of guiding the relative displacement of the inner container 32 in the vertical direction. The outer peripheral surface of the column 33 is preferably formed to be a smooth peripheral surface or the like. Additionally, the raw material supply source 30 includes a detector 34 configured to detect the height position of the inner container 32 inside the column 33.

An optical sensor capable of optically detecting the height position of the inner container 32 can be applied to the detector 34, for example. As an example of this, the detector 34 may be a sensor configured to detect the distance from the installation position of the column 33 to the top wall 323 of the inner container 32 on the upper side in the vertical direction and obtain the height position of the inner container 32 based on the detected distance. The obtained height position of the inner container 32 becomes an index related to the weight of the entire inner container 32. The detector 34 is communicably connected to the controller 9 and transmits the detection result of the height position of the inner container 32 to the controller 9. Here, the type of the detector 34 is not limited to an optical sensor, but a capacitance sensor, an ultrasonic sensor, or the like may be applied. Additionally, the detector 34 may be an encoder configured to detect a linear scale installed along the axial direction of the inner container 32. Additionally, the detector 34 may be a magnetic sensor configured to read a magnet embedded in the inner container 32.

The inner container 32 is a container for directly containing the raw material (a solid raw material SM) in the space 31s of the outer container 31. The inner container 32 has a bottom wall 321, a side wall 322, and a top wall 323, and is formed in a cylindrical (or rectangular) shape smaller than the outer container 31. A containment space 32s for the solid raw material SM is provided inside the inner container 32. As the solid raw material SM contained in the inner container 32, an example of a spherical solid is illustrated in FIG. 2, but the solid raw material SM is not limited to this, and may be in the form of pellets, powders, or the like.

As the top wall 323 of the inner container 32, a mesh 323m for allowing the raw material gas vaporized from the solid raw material SM to flow out is provided. With this, the inner container 32 can allow the raw material gas to flow upward. Here, the top wall 323 is not limited to the mesh 323m, but may be simply an open structure.

Additionally, to the top wall 323 of the inner container 32, a filling pipe 40 for filling the inner container 32 with the solid raw material SM may be attached, as illustrated by a dash-dot-dot line in FIG. 2. The filling pipe 40 penetrates through the outer container 31 and is connected to a supply hopper (not illustrated) for the solid raw material SM provided outside. The filling pipe 40 inside the outer container 31 is configured so as not to directly touch the inner container 32. With this, the inner container 32 can be smoothly displaced. Alternatively, the filling pipe 40 may be formed of a bellows, and the solid raw material SM may be filled into the containment space 32s while allowing the displacement of the inner container 32.

The bottom wall 321 of the inner container 32 is formed in a tapered shape (a funnel shape) projecting downward in the vertical direction toward the central axis. With this, the solid raw material SM contained in the containment space 32s is induced to gather near the central axis of the inner container 32.

Additionally, the inner container 32 has a hole 32h at the central axis where the column 33 is inserted and disposed. The hole 32h is formed in a circular cross section having a diameter slightly greater than the diameter of the column 33, and extends from the opening of the bottom wall 321 to the top wall 323. The column 33 of the outer container 31 is housed in the hole 32h, and thus the horizontal movement of the inner container 32 is restricted. An inner wall of the inner container 32 constituting the hole 32h is formed to be a smooth peripheral surface slidable with respect to the outer peripheral surface of the column 33.

Furthermore, the inner container 32 has a labyrinth structure 324 on the upper side of the containment space 32s. The labyrinth structure 324 prevents the solid raw material from escaping from the inner container 32 and entering the gas supply path 21 even if the solid raw material moves up due to heating of the solid raw material SM, supply of the solid raw material SM, or the like. When the filling pipe 40 is installed, for example, the labyrinth structure 324 may be formed by overlapping inclined plates in order to move the solid raw material SM to be filled from the filling pipe 40 downward.

The raw material supply source 30 includes a heater 35 configured to heat the solid raw material SM in the outer container 31. For example, the heater 35 is embedded in the bottom wall 311 of the outer container 31. To the heater 35, a structure such as an electric heating wire or sheet can be applied. Here, the position where the heater 35 is installed is not particularly limited and the heater 35 may be disposed outside the outer container 31 or within the space 31s of the outer container 31. Additionally, the heater 35 may be provided not only in the bottom wall 311 but also in the side wall 312.

The raw material supply source 30 includes a heat exchange structure 36 between the bottom wall 311 of the outer container 31 and the bottom wall 321 of the inner container 32. For example, the heat exchange structure 36 is formed by a plurality of fins 361 projecting from the bottom wall 311 of the outer container 31 toward the upper side in the vertical direction and a plurality of fins 362 projecting from the bottom wall 321 of the inner container 32 toward the lower side in the vertical direction. The fins 361 and 362 are alternately arranged in the lateral direction (the horizontal direction), and heat exchange can be performed between adjacent fins 361 and 362 without contact. With this, the heat exchange structure 36 can easily transmit heat heated by the heater 35 to the solid raw material SM of the inner container 32.

The distance between the fins 361 and 362 is greater than the distance between the outer peripheral surface of the column 33 and the inner peripheral surface of the hole 32h of the inner container 32. Therefore, interference between the fins 361 and 362 is avoided when the inner container 32 is displaced. Here, the heat exchange structure 36 is not limited to the above-described structure, and can have various configurations. For example, the heat exchange structure 36 may have a structure in which the bottom wall 321 of the inner container 32 is made thick and includes a plurality of holes, while the bottom wall 311 of the outer container 31 includes a plurality of rods inserted into the holes.

The raw material supply source 30 is configured to support the inner container 32 in the outer container 31 by an elastic member 37. Specifically, the elastic member 37 includes a lower spring member 371 disposed between the bottom wall 311 of the outer container 31 and the bottom wall 321 of the inner container 32, and an upper spring member 372 disposed between the top wall 313 of the outer container 31 and the top wall 323 of the inner container 32. Here, the elastic member 37 supporting the inner container 32 may include at least one of the lower spring member 371 or the upper spring member 372 without having both the lower spring member 371 and the upper spring member 372. Additionally, the elastic member 37 is not limited to a spring, but other members such as a rubber material may be applied.

For example, the lower spring member 371 is provided in the vicinity of the column 33 and the hole 32h so as to be concentric with the central axis. The lower spring member 371 elastically supports the bottom wall 321 of the inner container 32 near its central axis, while a plurality of upper spring members 372 are provided in the circumferential direction near the outer periphery of the inner container 32 to elastically suspend the inner container 32.

As described above, the inner container 32 floats in the space 31s due to the elastic member 37, and thus the height position in the space 31s changes according to the remaining amount of the solid raw material SM and the spring constant of the elastic member 37. For example, in a state where the inner container 32 is filled with a large amount of the solid raw material SM, the inner container 32 becomes heavy and is located on the lower side of the space 31s. In a state where the inner container 32 is filled with a small amount of the solid raw material SM, the inner container 32 becomes light and is displaced to the upper side of the space 31s. That is, the inner container 32 becomes lighter by the consumed amount of the solid raw material SM, and is pushed upward by the elastic member 37. By bringing the top wall 323 of the inner container 32 closer to the top wall 313 of the outer container 31 in accordance with the consumption of the solid raw material SM, the vaporized raw material gas can be delivered more efficiently.

The controller 9 can recognize the remaining amount of the solid raw material SM in the inner container 32 by using the detection result of the height position in the inner container 32. In other words, the controller 9 functions as an arithmetic unit configured to calculate the remaining amount of the solid raw material SM based on the index related to the weight of the inner container 32.

Furthermore, the raw material supply source 30 may include a magnetic field generator 39 on the outer peripheral surface of the outer container 31, and the inner container 32 may be formed of a magnetic material. The magnetic field generator 39 is connected to the controller 9, generates a magnetic field under the control of the controller 9, and causes the magnetic field to act on the inner container 32, which is formed of a magnetic material. With this, for example, when the inner container 32 is displaced in the vertical direction, the magnetic field of the magnetic field generator 39 can act as a damper for suppressing the vibration of the inner container 32.

Here, the vibration generated by the displacement of the inner container 32 is detected as a detection result indicating that the amplitude of the height position repeats with respect to the height position detected by the detector 34. Therefore, after receiving the detection result of the detector 34, the controller 9 preferably calculates one height position by performing a Fourier transform with respect to the height position of the amplitude on the time axis. With this, even if the inner container 32 vibrates, the controller 9 can obtain an appropriate height position.

The semiconductor manufacturing system 100 and the gas supply mechanism 2 according to the embodiment are basically configured as described above, and the operations thereof will be described below.

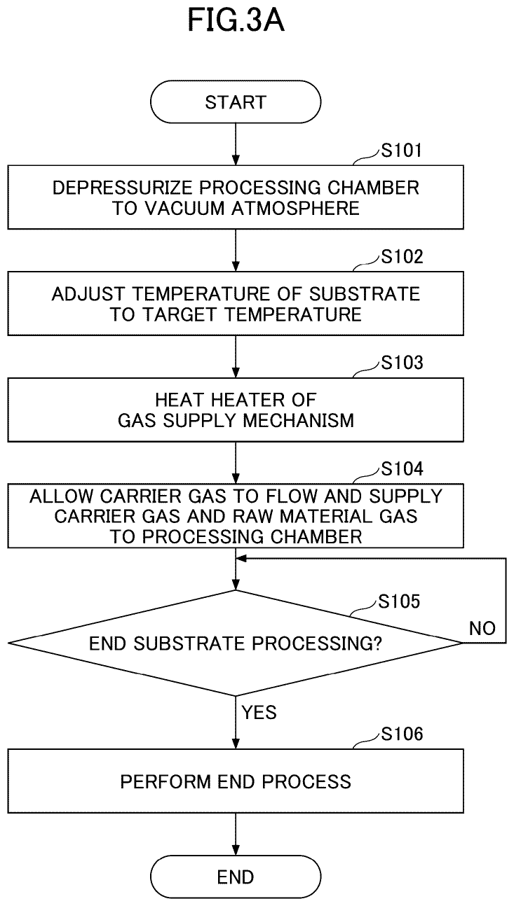

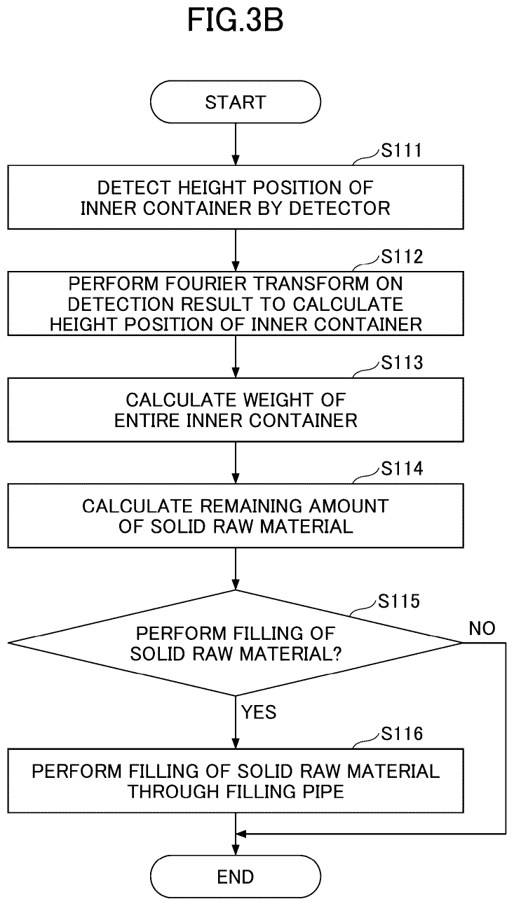

FIG. 3A is a flowchart illustrating an example of a substrate processing method of the semiconductor manufacturing system 100. FIG. 3B is a flowchart illustrating an example of a remaining amount monitoring method. The controller 9 of the semiconductor manufacturing system 100 performs substrate processing on the substrate W in the semiconductor manufacturing apparatus 1. At this time, the controller 9 controls steps S101 to S106 of the substrate processing method illustrated in FIG. 3A. Here, although the substrate processing method of the semiconductor manufacturing apparatus 1 that performs the above-described film deposition processing will be described below, it is of course possible to use substantially the same processing flow for other substrate processing such as etching processing.

Specifically, while the substrate W is mounted on the substrate support 11, the controller 9 controls the gas exhaust section 13 to depressurize the processing space 10s of the processing chamber 10 to a target pressure (the vacuum atmosphere) (step S101). By sucking the processing space 10s of the processing chamber 10, the gas exhaust section 13 also applies suction force to the outer container 31 via the gas supply path 21 that opens the valve 22. That is, the gas exhaust section 13 can also suck the gas in the space 31s of the outer container 31. With this, the space 31s of the outer container 31 is depressurized to the vacuum atmosphere, which is lower than the atmospheric pressure.

Additionally, the controller 9 adjusts the temperature of the substrate W to a target temperature by the temperature adjustment module installed in the substrate support 11 (step S102).

After the pressure of the processing chamber 10 reaches the target pressure and the temperature of the substrate W reaches the target temperature, the controller 9 controls the gas supply mechanism 2 to supply the processing gas into the processing chamber 10 to start substrate processing. Specifically, the gas supply mechanism 2 heats the heater 35 of the outer container 31 to transfer heat to the solid raw material SM in the inner container 32 via the heat exchange structure 36, thereby vaporizing the solid raw material SM to generate the raw material gas (step S103). Here, the timing of heating the solid raw material SM is not particularly limited, and may be, for example, at the same time as step S101 or step S102 or before these steps.

After the raw material gas flows into the outer container 31, the gas supply mechanism 2 opens the valve 25 to allow the carrier gas in the storage tank 27 to flow, and supplies the raw material gas and carrier gas to the processing chamber 10 (step S104). Specifically, the carrier gas flows into the space 31s of the outer container 31 via the carrier gas supply path 24 and is mixed with the raw material gas in the space 31s. Then, the mixed raw material gas and carrier gas flows into the gas supply path 21, is supplied to the shower head 12 via the gas supply path 21, is diffused in the shower head 12, and is discharged into the processing space 10s of the processing chamber 10. The raw material gas discharged into the processing space 10s adheres to the surface of the substrate W mounted on the substrate support 11. While the raw material gas is supplied to the substrate W, the controller 9 continues to perform the depressurization by suction of the gas exhaust section 13 and the adjustment of the temperature by the temperature adjustment module to adjust the film quality, film thickness, and the like of the film formed on the substrate W.

Additionally, during the substrate processing, the controller 9 determines the end timing of the substrate processing (step S105). For example, the controller 9 measures the execution period of the substrate processing and determines whether the execution period has reached a target period set in a recipe. If the substrate processing is not to be ended (step S105: NO), the supply of the raw material gas and carrier gas in the substrate processing, the depressurization by the gas exhaust section 13, and the temperature adjustment by the temperature adjustment module are continued. If the substrate processing is to be ended (step S105: YES), the process proceeds to step S106.

In step S106, the controller 9 performs an end process of the substrate processing. For example, in the end process, the gas supply mechanism 2 stops the supply of the raw material gas and carrier gas and stops the heating of the solid raw material SM. Further, in the end process, the gas suction by the gas exhaust section 13 is stopped, the temperature adjustment by the temperature adjustment module is stopped, and the like.

By performing the substrate processing method described above, the semiconductor manufacturing apparatus 1 can deposit a film having a desired thickness on the substrate W by using the raw material gas. At this time, the gas supply mechanism 2 can supply the raw material gas to the processing chamber 10 from the raw material supply source 30 without stagnation. Specifically, the heated inner container 32 causes the raw material gas to flow out to the upper side of the space 31s of the outer container 31, and in the outer container 31, the carrier gas supplied to the upper side of the space 31s by the carrier gas supply path 24 flows so as to push out the raw material gas. Therefore, the raw material gas and the carrier gas flow into the gas supply path 21 connected to the outer container 31 with almost no retention in the space 31s. In particular, when the remaining amount of the solid raw material SM becomes small, the inner container 32 can easily cause the raw material gas to flow out by the inner container 32 being moved to the upper side of the space 31s by the elastic member (the lower spring member 371 and the upper spring member 372).

Then, the controller 9 performs the remaining amount monitoring method of monitoring the remaining amount of the solid raw material SM in the inner container 32 after the supply of the raw material gas is stopped by the gas supply mechanism 2. For example, the remaining amount monitoring method performs a processing flow as illustrated in FIG. 3B. Here, the remaining amount monitoring method may be performed even during the supply of the raw material gas and the remaining amount of the solid raw material SM may be continuously monitored.

Specifically, the controller 9 detects the height position of the inner container 32 containing the raw material by the detector 34 installed in the column 33 of the outer container 31 (step S111). At the time of detection by the detector 34, the space 31s of the outer container 31 is depressurized to the vacuum atmosphere, which is lower than the atmospheric pressure, by suction of the gas exhaust section 13. Thus, the inner container 32 can smoothly move the raw material gas from the containment space 32s and be displaced within the space 31s with little influence of other gases. Therefore, the detector 34 can satisfactorily detect the height position of the inner container 32.

However, the inner container 32 is supported by the elastic member 37 (the lower spring member 371 and the upper spring member 372), and thus the inner container 32 may vibrate due to the displacement of the height position caused by the decrease of the remaining amount of the solid raw material SM. The detection result obtained from the detector 34 is a height position that repeatedly oscillates on the time axis. Therefore, the controller 9 calculates an appropriate height position by performing a Fourier transform on the oscillating results included in the detection result (step S112).

The controller 9 calculates the weight of the entire inner container 32 containing the solid raw material SM based on the calculated height position (step S113). For example, the controller 9 includes, in advance, a function or table representing the relationship between the spring constant of the elastic member, the height position, and the weight of the entire inner container 32, and calculates the weight of the entire inner container 32 using the function or table and the calculated height position.

Furthermore, the controller 9 calculates the remaining amount of the solid raw material SM by subtracting the weight of the empty inner container 32 stored in advance from the weight of the entire inner container 32 (step S114). By calculating the remaining amount of the raw material based on the relative position (height position) of the inner container 32 with respect to the outer container 31 in such a way, the controller 9 can accurately obtain the remaining amount of the solid raw material SM. Here, the controller 9 may be configured to directly calculate the remaining amount of the solid raw material SM by using a function, a table, or the like from the calculated height position of the inner container 32.

Additionally, the controller 9 has a determination threshold for starting the filling of the raw material in advance, and compares the calculated remaining amount of the solid raw material SM with the determination threshold to determine whether to start the filling of the solid raw material SM (step S115). If the remaining amount of the solid raw material SM is less than the determination threshold (step S115: YES), the process proceeds to step S116.

In step S116, the controller 9 supplies the solid raw material SM to the inner container 32 via the filling pipe 40. With this, the inner container 32 is filled with a certain amount of the solid raw material SM, and the inner container 32 displaced to the upper side of the space 31s is lowered to the lower side in accordance with the weight of the solid raw material SM. When step S116 ends, the controller 9 ends the processing flow of the material monitoring method.

If the remaining amount of the solid raw material SM is greater than or equal to the determination threshold (step S115: NO), it is determined that the filling of the raw material is not performed, and the processing flow ends without performing step S116. When monitoring the remaining amount of the solid raw material SM again, the controller 9 repeats steps from step S1.

As described above, the remaining amount monitoring method can easily recognize the remaining amount of the solid raw material SM based on the height position of the inner container 32 with respect to the outer container 31. In particular, the space 31s of the outer container 31 is depressurized to the vacuum atmosphere, which is lower than the atmospheric pressure, and thus the influence of gas can be suppressed as much as possible and the remaining amount of the solid raw material SM can be accurately obtained. With this, the remaining amount monitoring method can replenish the solid raw material SM at an appropriate timing.

Here, the gas supply mechanism 2, the semiconductor manufacturing system 100, and the remaining amount monitoring method according to the embodiment are not limited to the above-described embodiments, and various modifications can be adopted. For example, when the remaining amount of the solid raw material SM is calculated while the raw material gas is being supplied in the substrate processing, it is preferable to continue the substrate processing without performing the filling of the solid raw material SM even if the remaining amount of the solid raw material SM is less than the determination threshold during the substrate processing. Then, the filling of the solid raw material SM is performed after the completion of the substrate processing. With this, the semiconductor manufacturing system 100 can stably perform the substrate processing by avoiding temperature changes and gas changes associated with the filling of the solid raw material SM during the substrate processing.

Additionally, in the above embodiments, the inner container 32 is filled with the solid raw material SM via the filling pipe 40, but the gas supply mechanism 2 may be configured to replace the raw material supply source 30 without providing the filling pipe 40. For example, the remaining amount monitoring method compares the remaining amount of the solid raw material SM with the determination threshold, and when the remaining amount of the solid raw material SM becomes less than the determination threshold, it notifies the user of information prompting the replacement of the raw material supply source 30. With this, the user can replace the raw material supply source 30 at an appropriate timing. Here, the replacement of the raw material supply source 30 may be a configuration in which both the outer container 31 and the inner container 32 are replaced, or a configuration in which only the inner container 32 is replaced.

Additionally, the semiconductor manufacturing system 100 may include a plurality of gas supply mechanisms 2, and may be configured to supply the raw material gas from each of the gas supply mechanisms 2 to the processing chamber 10 at an appropriate timing. Furthermore, the gas supply mechanism 2 is not limited to a configuration in which the raw material gas flows together with the carrier gas, and may be configured to cause only the raw material gas to flow through the gas supply path 21 without providing the carrier gas supply depending on the type of the raw material.

Additionally, the gas supply mechanism 2 is not limited to using the gas exhaust section 13 of the semiconductor manufacturing apparatus 1 for depressurizing the space 31s of the outer container 31. For example, the gas supply mechanism 2 may be configured such that a dedicated depressurizing mechanism is connected to the outer container 31, and the depressurizing mechanism depressurizes the space 31s to the vacuum atmosphere.

The gas supply mechanism 2 is not limited to using the detector 34 configured to detect the height position of the inner container 32 as the index related to the weight of the inner container 32. As an example, the gas supply mechanism 2 may be configured such that the weight of the inner container 32 is directly measured by a weighing device installed in the outer container 31.

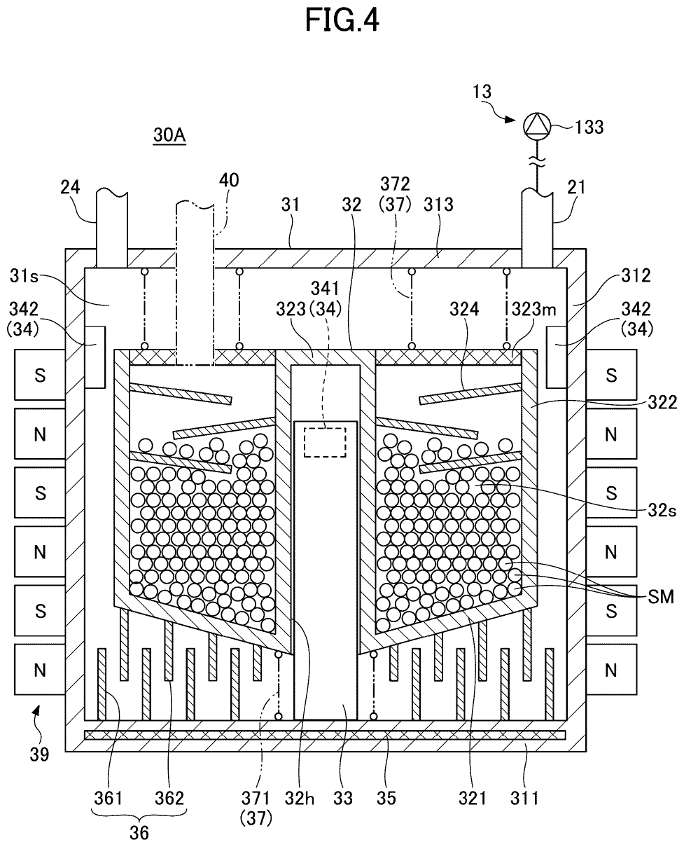

FIG. 4 is a cross-sectional view illustrating a raw material supply source 30A according to a modified example. As illustrated in FIG. 4, the raw material supply source 30A may include a plurality of detectors 34 configured to detect the position of the inner container 32. The plurality of detectors 34 include, for example, a first detector 341 provided in the column 33 and a plurality of second detectors 342 provided on the inner peripheral surface of the side wall 312 of the outer container 31. The plurality of second detectors 342 are installed at substantially equal intervals along the circumferential direction of the inner peripheral surface of the side wall 312. Each of the plurality of second detectors 342 detects the height position of the inner container 32 located on its side.

The controller 9 can calculate, by obtaining detection results detected by the first detector 341 and the second detectors 342, the horizontality of the inner container 32 by using these detection results. That is, if the height positions of the detectors 34 are close, the horizontality is high, and if the height positions are discrete, the horizontality is low, when the horizontality of the inner container 32 is low, it can be estimated that the solid raw material SM of the inner container 32 is unevenly distributed. Additionally, when the horizontality is low, the inner container 32 comes into contact with the outer container 31 with a strong frictional force, which affects the displacement. Therefore, in detecting the remaining amount of the solid raw material SM, the controller 9 corrects the height position of the inner container 32 in consideration of the horizontality. With this, the remaining amount of the solid raw material SM can be accurately detected. Additionally, when the horizontality is lower than a predetermined value, the controller 9 may perform processing, such as the filling of the solid raw material SM, notifying the user, increasing the heating amount of the heater 35 in the area where the solid raw material SM is largely located, or the like.

The technical concepts and effects of the present disclosure described in the above embodiments will be described below.

A first aspect of the present disclosure is the gas supply mechanism 2 configured to supply the raw material gas obtained by vaporizing the raw material (the solid raw material SM) and including the inner container 32 containing the raw material, the outer container 31 having the space 31s that houses the inner container 32 such that the inner container 32 is relatively displaceable and allowing the raw material gas generated from the raw material of the inner container 32 to flow out to the outside, and the detector 34 configured to detect the index related to the weight of the inner container 32. Before the detector 34 detects the index related to the weight of the inner container 32, the space 31s of the outer container 31 is depressurized to the vacuum atmosphere, which is lower than atmospheric pressure.

According to the above description, the gas supply mechanism 2 can stably and accurately detect the index related to the weight of the inner container 32 by depressurizing the space 31s of the outer container 31 to the vacuum atmosphere before the detector 34 detects the index related to the weight of the inner container 32. With this, the gas supply mechanism 2 can accurately recognize the remaining amount of the raw material (the solid raw material SM) contained in the inner container 32 based on the index related to the weight of the inner container 32. As a result, the gas supply mechanism 2 can prompt the filling of the raw material or the replacement of the inner container 32 at an appropriate timing.

Additionally, the gas supply mechanism 2 includes the elastic member 37 that elastically supports the inner container 32 at a position separated from the outer container 31. With this, the gas supply mechanism 2 can easily displacably support the inner container 32 and displace the height position of the inner container 32, which is the index related to the weight of the inner container 32.

Additionally, the detector 34 detects the relative height position of the inner container 32 with respect to the outer container 31 as the index related to the weight of the inner container 32. With this, the gas supply mechanism 2 can smoothly calculate the remaining amount of the raw material (the solid raw material SM) based on the height position of the inner container 32.

Additionally, an arithmetic unit (the controller 9) configured to calculate the remaining amount of the raw material (the solid raw material SM) in the inner container 32 based on the index related to the weight of the inner container 32 detected by the detector 34 is included. The arithmetic unit compares the calculated remaining amount of the raw material with the determination threshold, and if the remaining amount of the raw material is less than the determination threshold, the filling of the raw material is prompted or the replacement of the inner container is prompted. With this, the gas supply mechanism 2 can take an appropriate measure when the raw material is low.

Additionally, when the height position of the inner container 32 vibrated by the elastic member 37 is obtained from the detector 34, the arithmetic unit (the controller 9) calculates the height position of the inner container 32 by performing a Fourier transform. With this, the arithmetic unit can accurately calculate the height position of the inner container 32 that vibrates.

Additionally, the plurality of detectors 34 configured to detect the height position of the inner container 32 are included, and the arithmetic unit (the controller 9) recognizes the horizontality of the inner container 32 based on the height positions of the inner container 32 of the plurality of detectors 34. With this, the gas supply mechanism 2 can correct the remaining amount of raw material to be calculated based on the horizontality of the inner container 32.

Additionally, the inner container 32 is formed in a cylindrical shape having the hole 32h in the central axis, and the outer container 31 includes the column 33 that guides the displacement of the inner container 32 by being inserted into the hole 32h. With this, the gas supply mechanism 2 can stably displace the inner container 32.

Additionally, the detector 34 is installed in the column 33. With this, the gas supply mechanism 2 can detect the index related to the height position of the inner container 32 at a position sufficiently close to the inner container 32.

Additionally, the bottom wall 321 of the inner container 32 is formed in a tapered shape sloped downward in the vertical direction toward the central axis. With this, the inner container 32 can collect the raw material (the solid raw material SM) near the central axis, and the posture of the inner container 32 can be stabilized. Therefore, the gas supply mechanism 2 can more accurately detect the index related to the weight of the inner container 32 by the detector 34.

Furthermore, the inner container 32 is formed of a magnetic material, and the outer container 31 includes the magnetic field generator 39 configured to generate a magnetic field to the inner container 32. With this, the gas supply mechanism 2 can quickly converge the vibration in the displacement of the inner container 32 based on the magnetic field of the magnetic field generator 39.

Additionally, a second aspect of the present disclosure is the semiconductor manufacturing system 100 including the semiconductor manufacturing apparatus 1 configured to process a semiconductor, and the gas supply mechanism 2 configured to supply, to the semiconductor manufacturing apparatus 1, the raw material gas obtained by vaporizing the raw material. The gas supply mechanism 2 includes the inner container 32 containing the raw material, the outer container 31 having the space 31s in which the inner container 32 is housed such that the inner container 32 is relatively displaceable and allowing the raw material gas generated from the raw material of the inner container 32 to flow out to the outside, and the detector 34 configured to detect the index related to the weight of the inner container 32. Before the detector 34 detects the index related to the weight of the inner container 32, the space 31s of the outer container 31 is depressurized to the vacuum atmosphere, which is lower than atmospheric pressure. Even in this case, the semiconductor manufacturing system 100 can accurately recognize the remaining amount of the raw material.

Additionally, a third aspect of the present disclosure is the remaining amount monitoring method of monitoring the remaining amount of the raw material in the gas supply mechanism 2 configured to supply the raw material gas obtained by vaporizing the raw material (the solid raw material SM). The gas supply mechanism 2 includes the inner container 32 containing the raw material, the outer container 31 having the space 31s in which the inner container 32 is housed such that the inner container 32 is relatively displaceable and allowing the raw material gas generated from the raw material of the inner container 32 to flow out to the outside, and the detector 34 configured to detect the index related to the weight of the inner container 32. In the remaining amount monitoring method, the detector 34 detects the index related to the weight of the inner container 32 while the space 31s of the outer container 31 is depressurized to the vacuum atmosphere, which is lower than atmospheric pressure. Even in this case, the remaining amount monitoring method can accurately recognize the remaining amount of the raw material.

The gas supply mechanism 2, the semiconductor manufacturing system 100, and the remaining amount monitoring method according to the embodiments disclosed herein are exemplary in all respects and are not restrictive. The embodiments may be modified and improved in various ways without departing from the scope and spirit of the appended claims. The matters described in the above embodiments can also take other configurations as long as there is no contradiction, and can be combined as long as there is no contradiction.

The semiconductor manufacturing apparatus of the present disclosure can be applied to any of the following types of apparatuses: an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECR) apparatus, and a helicon wave plasma (HWP) apparatus.

What is claimed is:

1. A gas supply mechanism for supplying a raw material gas obtained by vaporizing a raw material, the gas supply mechanism comprising:
an inner container configured to contain the raw material;
an outer container having a space in which the inner container is accommodated such that the inner container is relatively displaceable and allowing the raw material gas generated from the raw material in the inner container to flow out to an outside; and
a detector configured to detect an index related to a weight of the inner container,
wherein the space of the outer container is depressurized to a vacuum atmosphere lower than an atmospheric pressure before the detector detects the index related to the weight of the inner container.

2. The gas supply mechanism as claimed in claim 1, further comprising an elastic member configured to elastically support the inner container at a position separated from the outer container.

3. The gas supply mechanism as claimed in claim 2, wherein the detector detects a relative height position of the inner container with respect to the outer container as the index related to the weight of the inner container.

4. The gas supply mechanism as claimed in claim 3, further comprising a controller configured to calculate a remaining amount of the raw material in the inner container based on the index related to the weight of the inner container detected by the detector,
wherein the controller compares the calculated remaining amount of the raw material with a determination threshold and prompts filling of the raw material or replacement of the inner container in response to determining that the calculated remaining amount of the raw material is less than the determination threshold.

5. The gas supply mechanism as claimed in claim 4, wherein the controller calculates the height position of the inner container by performing a Fourier transform, when the height position of the inner container vibrated by the elastic member is obtained from the detector.

6. The gas supply mechanism as claimed in claim 4, further comprising a plurality of said detectors configured to detect the height position of the inner container,
wherein the controller recognizes horizontality of the inner container based on the height position of the inner container of each of the plurality of the detectors.

7. The gas supply mechanism as claimed in claim 1,
wherein the inner container is formed in a cylindrical shape having a hole in a central axis, and
wherein the outer container includes a column inserted into the hole to guide displacement of the inner container.

8. The gas supply mechanism as claimed in claim 7, wherein the detector is installed in the column.

9. The gas supply mechanism as claimed in claim 1, wherein a bottom wall of the inner container is formed in a tapered shape sloped downward toward a central axis.

10. The gas supply mechanism as claimed in claim 1,
wherein the inner container is formed of a magnetic material, and
wherein the outer container includes a magnetic field generator configured to generate a magnetic field to the inner container.

11. A semiconductor manufacturing system comprising:
a semiconductor manufacturing apparatus configured to process a semiconductor; and
a gas supply mechanism configured to supply, to the semiconductor manufacturing apparatus, a raw material gas obtained by vaporizing a raw material,
wherein the gas supply mechanism includes:
an inner container configured to contain the raw material;
an outer container having a space in which the inner container is accommodated such that the inner container is relatively displaceable and allowing the raw material gas generated from the raw material of the inner container to flow out to an outside; and
a detector configured to detect an index related to a weight of the inner container,
wherein the space of the outer container is depressurized to a vacuum atmosphere lower than an atmospheric pressure before the detector detects the index related to the weight of the inner container.

12. A remaining amount monitoring method of monitoring, in a gas supply mechanism configured to supply a raw material gas obtained by vaporizing a raw material, a remaining amount of the raw material, the gas supply mechanism including:
an inner container configured to contain the raw material;
an outer container having a space in which the inner container is accommodated such that the inner container is relatively displaceable and allowing the raw material gas generated from the raw material of the inner container to flow out to an outside; and
a detector configured to detect an index related to a weight of the inner container, the remaining amount monitoring method comprising detecting, by the detector, the index related to the weight of the inner container in a state in which the space of the outer container is depressurized to a vacuum atmosphere lower than an atmospheric pressure.
